(19) United States
(12) Patent Application Publication
(10) Pub. No.: US 2026/0075806 A1
(43) Pub. Date: Mar. 12, 2026

(54) SEMICONDUCTOR DEVICES INCLUDING BACK GATE ELECTRODE

(71) Applicant: Samsung Electronics Co., Ltd., Suwon-si (KR)

(72) Inventors: SONGEUN BEACK, Suwon-si (KR); TAEKYONG KIM, Suwon-si (KR); TAEJIN PARK, Suwon-si (KR)

(21) Appl. No.: 19/172,823

(22) Filed: Apr. 8, 2025

(30) Foreign Application Priority Data
Sep. 10, 2024 (KR) 10-2024-0123079

(51) Int. Cl. H10B 12/00

(52) U.S. Cl. CPC H10B 12/33; H10B 12/02; H10B 12/482

(57) ABSTRACT

A semiconductor device comprises a cell transistor including a channel region; a back gate electrode that faces a side surface of the channel region and extends in a first horizontal direction; a bit line on the cell transistor and the back gate electrode, wherein the bit line extends in a second horizontal direction that intersects the first horizontal direction; a connection line on the back gate electrode, wherein the connection line extends in the second horizontal direction; and a back gate contact plug between the connection line and the back gate electrode, wherein the back gate contact plug electrically connects the connection line and the back gate electrode, wherein the bit line overlaps the connection line in the first horizontal direction, and wherein a first width of the connection line in the first horizontal direction is greater than a second width of the bit line in the first horizontal direction.

### CROSS-REFERENCE TO RELATED APPLICATIONS

This application claims benefit of priority to Korean Patent Application No. 10-2024-0123079 filed on Sep. 10, 2024 in the Korean Intellectual Property Office, the disclosure of which is incorporated herein by reference in its entirety.

### BACKGROUND OF THE INVENTION

Example embodiments relate to semiconductor devices including a back gate electrode, and methods for forming the same.

Research is being conducted to reduce a size of elements constituting a semiconductor device and to improve performance thereof. For example, in a DRAM, research is being conducted to reliably and stably form elements of which sizes are reduced, but as the sizes of the elements are reduced, dispersion characteristics of the semiconductor device may deteriorate.

### SUMMARY OF THE INVENTION

Example embodiments may provide a semiconductor device capable of increasing a degree of integration and improving performance.

Example embodiments may provide a method for forming the semiconductor device.

According to example embodiments, the semiconductor device includes a cell transistor that includes a channel region; a back gate electrode that faces a side surface of the channel region and extends in a first horizontal direction; a bit line on the cell transistor and the back gate electrode, wherein the bit line extends in a second horizontal direction that intersects the first horizontal direction; a connection line on the back gate electrode, wherein the connection line extends in the second horizontal direction; and a back gate contact plug between the connection line and the back gate electrode, wherein the back gate contact plug electrically connects the connection line and the back gate electrode, wherein the bit line overlaps the connection line in the first horizontal direction, and wherein a first width of the connection line in the first horizontal direction is greater than a second width of the bit line in the first horizontal direction.

According to example embodiments, the semiconductor device includes a cell transistor; first back gate electrodes that respectively extend in a first horizontal direction, wherein the first back gate electrodes overlap the cell transistor in a second horizontal direction that intersects the first horizontal direction; a first connection line and a second connection line on the first back gate electrodes, wherein the first connection line and the second connection line each extend in the second horizontal direction; bit lines between the first connection line and the second connection line, wherein the bit lines overlap the first connection line and the second connection line in the first horizontal direction and extend in the second horizontal direction; and first back gate contact plugs between the first back gate electrodes and the first connection line, wherein the first back gate contact plugs electrically connect the first back gate electrodes and the first connection line.

According to example embodiments, the semiconductor device includes cell transistors; back gate electrodes between adjacent ones of the cell transistors, wherein the back gate electrodes respectively extend in a first horizontal direction; conductive lines vertically overlapping the cell transistors and the back gate electrodes, wherein the conductive lines extend in a second horizontal direction that intersects the first horizontal direction; a first connection line that overlaps the conductive lines in the first horizontal direction and is adjacent a first outermost conductive line among the conductive lines; and first back gate contact plugs between the first connection line and respective ones of first back gate electrodes of the back gate electrodes, wherein the first back gate contact plugs electrically connect the first connection line and the respective ones of the first back gate electrodes.

### BRIEF DESCRIPTION OF DRAWINGS

The aspects, features, and advantages of the present inventive concept will be more clearly understood from the following detailed description, taken in conjunction with the accompanying drawings, in which:

FIGS. 1, 2, 3, and 4 are views illustrating a semiconductor device according to embodiments.

FIGS. 5, 6A, 6B, and 7 are views illustrating a semiconductor device according to an embodiment.

FIGS. 8A and 8B are cross-sectional views illustrating a semiconductor device according to an embodiment.

FIG. 9 is a cross-sectional view illustrating a semiconductor device according to an embodiment.

FIG. 10 is a cross-sectional view illustrating a semiconductor device according to an embodiment.

FIGS. 11A and 11B are views illustrating a semiconductor device according to an embodiment.

FIG. 12 is a cross-sectional view illustrating a semiconductor device according to an embodiment.

FIG. 13 is a cross-sectional view illustrating a semiconductor device according to an embodiment.

FIG. 14 is a plan view illustrating a semiconductor device according to an embodiment.

FIGS. 15, 16A, 16B, 17A, 17B, 18A, and 18B are views illustrating an illustrative example of a method for forming a semiconductor device according to an embodiment.

### DETAILED DESCRIPTION

Hereinafter, terms such as “upper,” “middle,” “lower,” or the like may be replaced with other terms, for example, terms such as “first,” “second,” “third,” or the like, and may be used to describe elements of the specification. Terms such as “first,” “second,” “third,” or the like may be used to describe various elements, but the elements are not limited by the terms, and a “first element” may be named a “second element.” In the specification, terms such as “lower,” “upper,” “upper end,” “lower end,” or the like may be terms described based on the drawings.

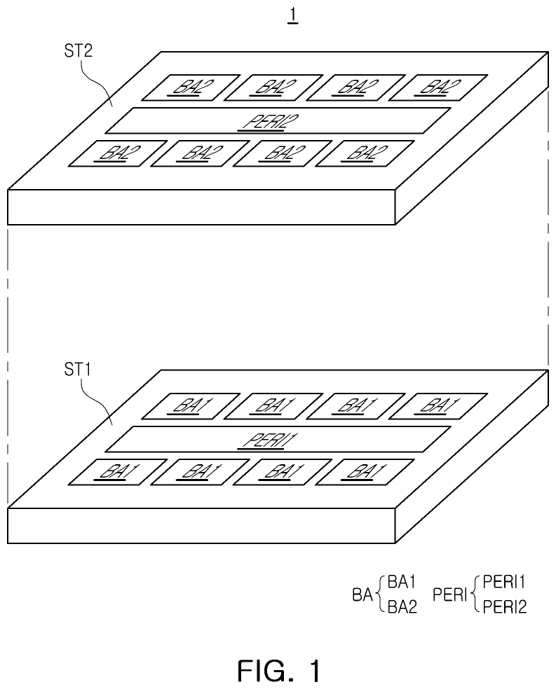

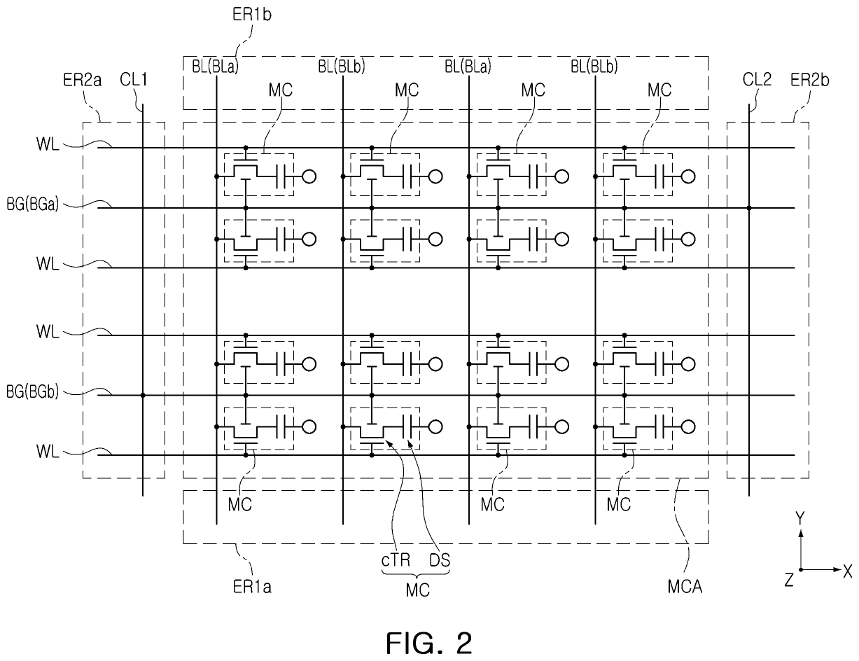

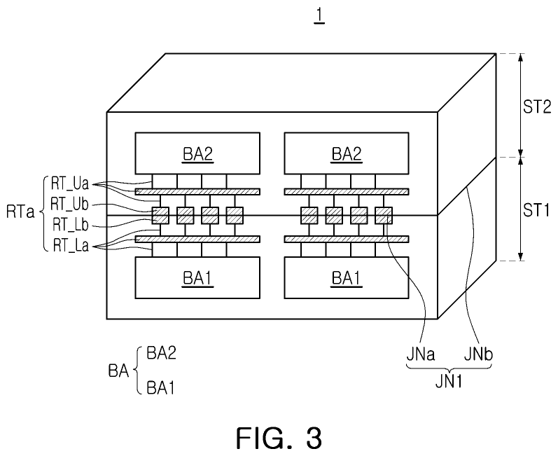

A semiconductor device 1 according to embodiments will be described with reference to FIGS. 1, 2, and 3. In FIGS. 1 to 3, FIG. 1 is a perspective view conceptually illustrating a semiconductor device 1 according to embodiments, FIG. 2 is a circuit diagram illustrating a circuit of a portion of the first structure ST1 of FIG. 1, and FIG. 3 is a perspective view conceptually illustrating an electrical connection relationship between the first and second structures ST1 and ST2 of FIG. 1.

Referring to FIGS. 1, 2, and 3, a semiconductor device 1 according to an embodiment may include a first structure ST1 and a second structure ST2 vertically overlapping (e.g., overlapping in Z direction) the first structure ST1. The second structure ST2 may be disposed on the first structure ST1. According to an embodiment, the second structure ST2 may be disposed below the first structure ST1.

In an embodiment, the first structure ST1 may be a first chip structure including memory cell array region MCA and memory cells MC, and the second structure ST2 may be a second chip structure including peripheral circuits such as a sense amplifier, a sub-word line driver, or the like, used for operations of the memory cells MC.

In an embodiment, the semiconductor device 1 may be formed by bonding the first structure ST1 and the second structure ST2 through a bonding process such as a wafer bonding process. For example, the first structure ST1 may be in contact with and bonded to the second structure ST2.

The semiconductor device 1 may include a plurality of banks BA and an outer peripheral region PERI.

The outer peripheral region PERI may include a first peripheral region PERI1 in the first structure ST1 and a second peripheral region PERI2 in the second structure ST2. The outer peripheral region PERI may be a peripheral region in which peripheral circuits for input/output of data or commands, or input of power/ground are disposed.

Each of the plurality of banks BA may include a first bank region BA1 in the first structure ST1 and a second bank region BA2 in the second structure ST2.

The first bank region BA1 in the first structure ST1 may include a memory cell array region MCA, and first, second, third, and fourth extension regions ER1a, ER1b, ER2a and ER2b.

In a second horizontal direction (e.g., Y direction), the first extension region ER1a, the memory cell array region MCA, and the second extension region ER1b may be disposed in sequence. The memory cell array region MCA may be disposed between the first and second extension regions ER1a and ER1b in the second horizontal direction.

In a first horizontal direction (e.g., X direction) , the third extension region ER2a, the memory cell array region MCA, and the fourth extension region ER2b may be disposed in sequence. The memory cell array region MCA may be disposed between the third and fourth extension regions ER2a and ER2b in the first horizontal direction.

The first bank region BA1 in the first structure ST1 may include memory cells MC disposed (e.g., arranged) in the first horizontal direction (e.g., X direction) and the second horizontal direction (e.g., Y direction), perpendicular to each other, in the memory cell array region MCA, word lines WL (electrically) connected to the memory cells MC and extending in the first horizontal direction (e.g., X direction), and bit lines BL (electrically) connected to the memory cells MC and extending in the second horizontal direction (e.g., Y direction).

The word lines WL may cross the memory cell array region MCA in the first horizontal direction (e.g., X direction), and may extend into the third and fourth extension regions ER2a and ER2b.

The bit lines BL may cross the memory cell array region MCA in the second horizontal direction (e.g., Y direction), and may extend into the first and second extension regions ER1a and ER1b.

The bit lines BL may include odd-numbered first bit lines BLa and even-numbered second bit lines BLb. The first bit lines BLa may be disposed alternately with the second bit lines BLb in the first horizontal direction (e.g., X direction).

Each of the memory cells MC may include a data storage structure DS that may serve as information storage, and a cell transistor cTR (electrically) connected to the data storage structure DS. In a memory such as a DRAM or the like, the data storage structure DS may be a cell capacitor that may store information.

The first bank region BA1 in the first structure ST1 may further include back gate electrodes BG crossing (e.g. overlapping in the first horizontal direction (e.g., X direction)) the memory cell array region MCA and extending into the third and fourth extension regions ER2a and ER2b. Each of the back gate electrodes BG may be disposed between a pair of word lines WL, adjacent to each other in the second horizontal direction (e.g., Y direction), among the word lines WL. Each of the back gate electrodes BG may extend in the first horizontal direction (e.g., X direction). The back gate electrodes BG may pass (extend) between (adjacent) cell transistors cTR (in the second horizontal direction (e.g., Y direction)), and may extend into the third and fourth extension regions ER2a and ER2b. Each of the back gate electrodes BG may be disposed between channel regions of the (adjacent) cell transistors cTR (in the second horizontal direction (e.g., Y direction)).

The back gate electrodes BG may include odd-numbered first back gate electrodes BGa and even-numbered second back gate electrodes BGb. The first back gate electrodes BGa may be disposed alternately with the second back gate electrodes BGb in the second horizontal direction (e.g., Y direction).

The first bank region BA1 in the first structure ST1 may further include connection lines CL1 and CL2 parallel to the bit lines BL. Each of the connection lines CL1 and CL2 may extend in the second horizontal direction (e.g., Y direction). The connection lines CL1 and CL2 may be disposed at (substantially) the same level as the bit lines BL, and may be formed of the same material as the bit lines BL. The connection lines CL1 and CL2 may include a first connection line CL1 crossing (e.g., overlapping in the second horizontal direction (e.g., Y direction)) the third extension region ER2a, and a second connection line CL2 crossing (e.g., overlapping in the second horizontal direction (e.g., Y direction)) the fourth extension region ER2b. Herein, the term “level”, “vertical level”, “height”, or the like may refer to a relative location with respect to a reference element in the vertical direction (e.g., Z direction). For example, a level, a vertical level, height, or the like may be a distance from the lower surface of the first structure ST1 in the vertical direction. A higher level may mean a farther distance from the lower surface of the first structure ST1 in the vertical direction, and a lower level may mean a closer distance to the lower surface of the first structure ST1 in the vertical direction.

The connection lines CL1 and CL2 and the back gate electrodes BG may be (electrically) connected in the third and fourth extension regions ER2a and ER2b, respectively. For example, the first back gate electrodes BGa may be (electrically) connected to the second connection line CL2 in the fourth extension region ER2b, and the second back gate electrodes BGb may be (electrically) connected to the first connection line CL1 in the third extension region ER2a.

The second bank region BA2 in the second structure ST2 may include peripheral circuits such as a sense amplifier (electrically) connected to the bit lines BL in the memory cell array region MCA, a sub-word line driver (electrically) connected to the word lines WL in the memory cell array region MCA, a back gate control circuit (electrically) connected to the back gate electrodes BG in a memory region, or the like.

The first and second structures ST1 and ST2 may further include a routing wiring structure RTa (electrically) connecting the first bank region BA1 and the second bank region BA2. For example, the routing wiring structure RTa may include a first routing wiring structure (RT_La and RT_Lb) disposed in the first structure ST1, and a second routing wiring structure (RT_Ua and RT_Ub) disposed in the second structure ST2.

The first routing wiring structure (RT_La and RT_Lb) may include a first wiring structure RT_La (electrically) connected to the first bank region BA1, and first bonding pads RT_Lb (electrically) connected to the first wiring structure RT_La. The second routing wiring structure (RT_Ua and RT_Ub) may include a second wiring structure RT_Ua (electrically) connected to the second bank region BA2, and second bonding pads RT_Ub (electrically) connected to the second wiring structure RT_Ua.

The first bonding pads RT_Lb and the second bonding pads RT_Ub may be in contact with each other, and may be bonded. For example, the first bonding pads RT_Lb and the second bonding pads RT_Ub may include copper, and may be bonded to each other by a metal-to-metal bonding process. Therefore, a bonding surface JN1 between the first structure ST1 and the second structure ST2 may include metal-to-metal bonding regions JNa in which the first bonding pads RT_Lb of the first structure ST1 and the second bonding pads RT_Ub of the second structure ST2 are bonded to each other, and dielectric-to-dielectric bonding regions JNb in which a dielectric of the first structure ST1 and a dielectric of the second structure ST2 are bonded to each other.

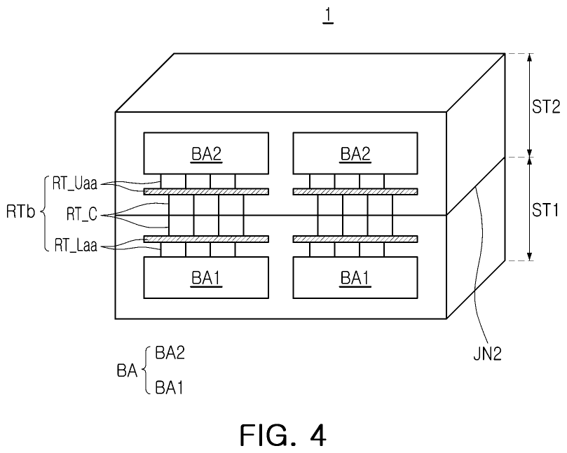

Next, an illustrative example of the routing wiring structure RTa and the bonding surface JN1, described above, will be described with reference to FIG. 4. FIG. 4 is a conceptual perspective view corresponding to an illustrative example of the routing wiring structure RTa and the bonding surface JN1, described in FIG. 3.

In an illustrative example, referring to FIG. 4, the routing wiring structure RTa described in FIG. 3 may be replaced with a routing wiring structure RTb in which the first bonding pads RT_Lb and the second bonding pads RT_Ub may be omitted, and the bonding surface JN1 described in FIG. 3 may be replaced with a bonding surface JN2 in which the metal-to-metal bonding regions JNa may be omitted.

The routing wiring structure RTb may include a first wiring structure RT_Laa included in a first structure ST1 and (electrically) connected to a first bank region BA1, a second wiring structure RT_Uaa included in a second structure ST2 and (electrically) connected to a second bank region BA2, and a connection structure RT_C extending between the first structure ST1 and the second structure ST2 and (electrically) connecting the first and second wiring structures RT_Laa and RT_Uaa.

The bonding surface JN2 between the first structure ST1 and the second structure ST2 may be formed as a dielectric bonding surface in which a dielectric of the first structure ST1 and a dielectric of the second structure ST2 are bonded to each other. The connection structure RT_C may include a through-via or a through-connection plug that may penetrate (extend through) the bonding surface JN2.

Hereinafter, illustrative examples of the first structure ST1 of the semiconductor device 1 will be described with reference to FIGS. 1 to 3. Hereinafter, illustrative examples of the first structure ST1 described in FIGS. 1 to 3 will be described, but in illustrative embodiments described below, the routing wiring structure RTa and the bonding surface JN1 described in FIG. 3 may be replaced with the routing wiring structure RTb and the bonding surface JN2 described in FIG. 4. In addition, illustrative embodiments described below may be combined with each other to form one illustrative embodiment.

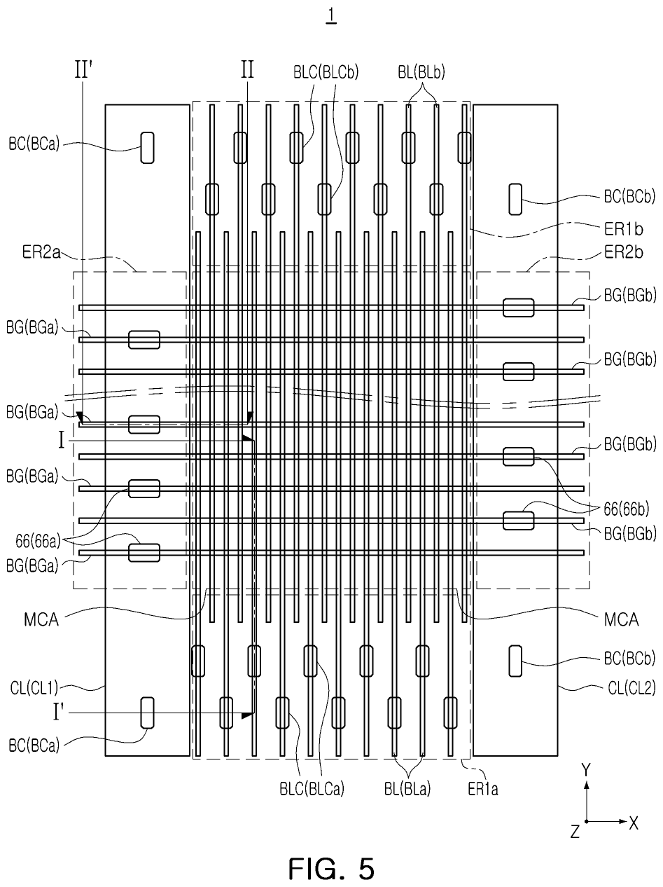

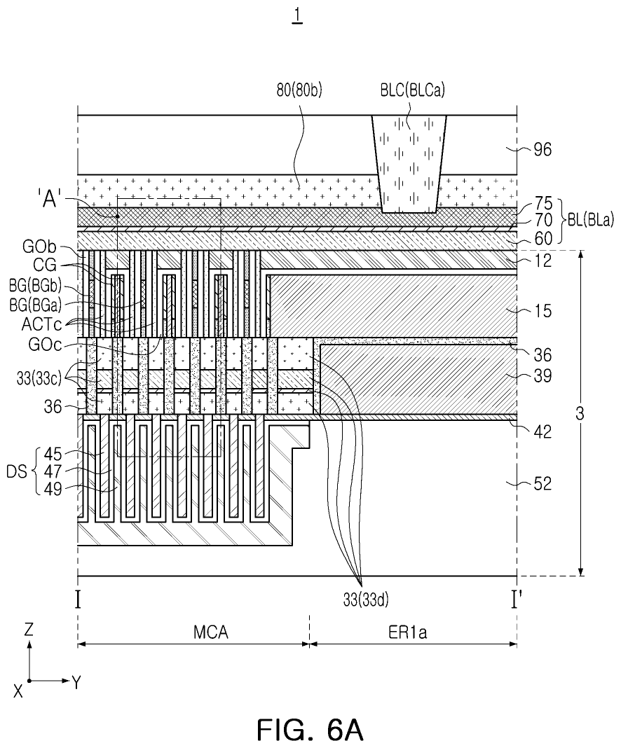

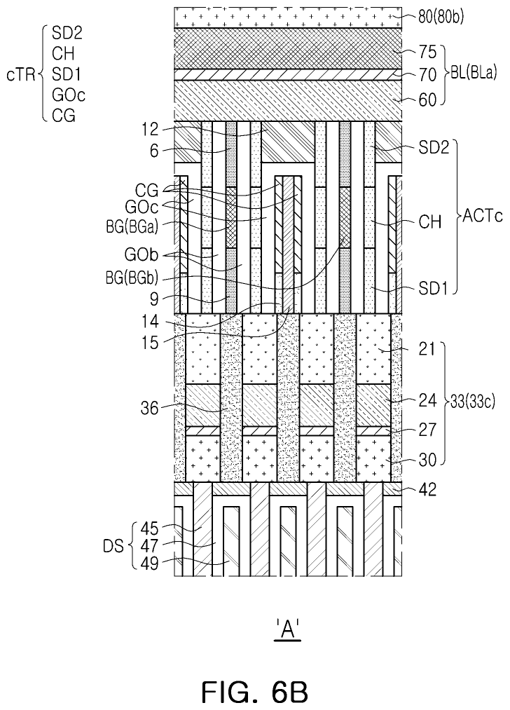

Illustrative examples of the first structure ST1 of the semiconductor device 1 will be described with reference to FIGS. 5, 6A, 6B, and 7. In FIGS. 5, 6A, 6B, and 7, FIG. 5 is be a plan view illustrating an illustrative example of the memory cell array region MCA and the first, second, third, and fourth extension regions ER1a, ER1b, ER2a, and ER2b described in FIG. 2, FIG. 6A is a cross-sectional view illustrating a region taken along line I-I′ of FIG. 5, FIG. 6B is an enlarged partial view illustrating a region indicated by ‘A’ of FIG. 6A, and 7 is a cross-sectional view illustrating a region taken along line II-II′ of FIG. 5.

Referring to FIGS. 1 to 3, FIGS. 5, 6A, 6B, and 7, the first structure ST1 of the semiconductor device 1 may include a structure 3 including cell transistors cTR and back gate electrodes BG, conductive lines BL and connection lines CL, disposed on the structure 3, and back gate contact plugs 66 (electrically) connecting the connection lines CL and the back gate electrodes BG.

The structure 3 may further include active patterns ACTc. Each of the active patterns ACTc may include a semiconductor material that may be used as a channel region of a transistor. For example, each of the active patterns ACTc may include a silicon layer, a germanium layer, a silicon-germanium layer, an oxide semiconductor layer, and/or a two-dimensional material layer having semiconductor properties. For example, each of the active patterns ACTc may include a single crystal silicon layer. The active patterns ACTc may be disposed (e.g., arranged) in the first horizontal direction (X) and the second horizontal direction (Y), perpendicular to each other.

Each of the cell transistors cTR may include a first source/drain region SD1, a second source/drain region SD2 on the first source/drain region SD1 (in the vertical direction (e.g., Z direction)), a channel region CH between the first source/drain region SD1 and the second source/drain region SD2 (in the vertical direction (e.g., Z direction)), a cell gate electrode CG facing a first side surface of the channel region CH, and a cell gate dielectric layer GOc between the channel region CH and the cell gate electrode CG (in the second horizontal direction (e.g., Y direction). The second source/drain region SD2 may be disposed on a level, higher than a level of the first source/drain region SD1. The channel region CH may be a vertical channel region.

The cell gate electrodes CG may be the word lines WL. The cell gate electrodes CG may extend in the first horizontal direction (X), may cross the memory cell array region MCA, and may extend into the third and fourth extension regions ER2a and ER2b.

Each of the cell gate electrodes CG may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi and/or a combination thereof, but is not limited thereto. Each of the cell gate electrodes CG may include a single layer or multiple layers of the conductive materials described above, but is not limited thereto.

The first and second source/drain regions SD1 and SD2 and the channel areas CH may be formed in the active patterns ACTc. Each of the active patterns ACTc may include the first source/drain region SD1, the channel region CH, and the second source/drain region SD2.

The cell transistors cTR may be disposed on the same level. In a back gate electrode BG and a cell transistor cTR adjacent to each other, among the back gate electrodes BG and the cell transistors cTR, the back gate electrode BG may be disposed at the same level as a portion of the cell transistor cTR. For example, the back gate electrode BG may be disposed at the same level as at least a portion of the cell gate electrode CG of the cell transistor cTR, and may be disposed at the same level as at least a portion of the channel region CH of the cell transistor cTR. For example, the back gate electrode BG may overlap the cell gate electrode CG and/or the channel region CH in the second horizontal direction (e.g., Y direction).

The back gate electrodes BG may pass (extend) between the cell transistors cTR (spaced apart from each other in the second horizontal direction (e.g., Y direction)), and may extend in the first horizontal direction (e.g., X direction), respectively. The back gate electrodes BG may cross the memory cell array region MCA, and may extend into the third and fourth extension regions ER2a and ER2b.

Each of the back gate electrodes BG may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi and/or a combination thereof, but is not limited thereto. Each of the back gate electrodes BG may include a single layer or multiple layers of the conductive materials described above, but is not limited thereto.

In an example, a vertical length (a length in the vertical direction (e.g., Z direction)) of each of the cell gate electrodes CG may be different from a vertical length (a length in the vertical direction (e.g., Z direction)) of each of the back gate electrodes BG. For example, the vertical length of each of the cell gate electrodes CG may be greater than the vertical length of each of the back gate electrodes BG. However, an embodiment is not limited thereto. For example, the vertical length of each of the cell gate electrodes CG may be equal to or less than the vertical length of each of the back gate electrodes BG.

The structure 3 may further include a back gate dielectric layer GOb between the back gate electrodes BG and the active patterns ACTc (in the second horizontal direction (e.g., Y direction)). The back gate electrodes BG may face (may overlap in the second horizonal direction (e.g., Y direction)) the channel regions CH of the active patterns ACTc.

In an embodiment, when viewed based on one of the active patterns ACTc, the channel region CH may be disposed between one of the cell gate electrodes CG and one of the back gate electrodes BG (in the second horizontal direction (e.g., Y direction)). The cell gate electrode CG may face a first side surface of the channel region CH, and the back gate electrode BG may face a second side surface of the channel region CH. The first side surface of the channel region CH may be opposite to the second side surface of the channel region CH in the second horizontal direction (e.g., Y direction).

The conductive lines BL may be (electrically) connected to the second source/drain regions SD2 of the cell transistors cTR. The conductive lines BL may be bit lines (e.g., the bit lines BL in FIG. 2). Each of the conductive lines BL may extend in the second horizontal direction (e.g., Y direction). The conductive lines BL may cross the memory cell array region MCA, and may extend into the first and second extension regions ER1a and ER1b. The odd-numbered first bit lines BLa in FIG. 2 described above may be first conductive lines BLa among the conductive lines BL, and the even-numbered second bit lines BLb in FIG. 2 described above may be second conductive lines BLb among the conductive lines BL.

The connection lines CL may be parallel to each other, and may extend in the second horizontal direction (e.g., Y direction), respectively. The connection lines CL may include a first connection line CL1 and a second connection line CL2. The first connection line CL1 may cross (e.g., overlap in the vertical direction (e.g., Z direction)) the third extension region ER2a, and may extend in the second horizontal direction (e.g., Y direction). The second connection line CL2 may cross (e.g., overlap in the vertical direction (e.g., Z direction)) the fourth extension region ER2b, and may extend in the second horizontal direction (e.g., Y direction). The conductive lines BL may be disposed between the first and second connection lines CL1 and CL2 (in the first horizontal direction (e.g., X direction)).

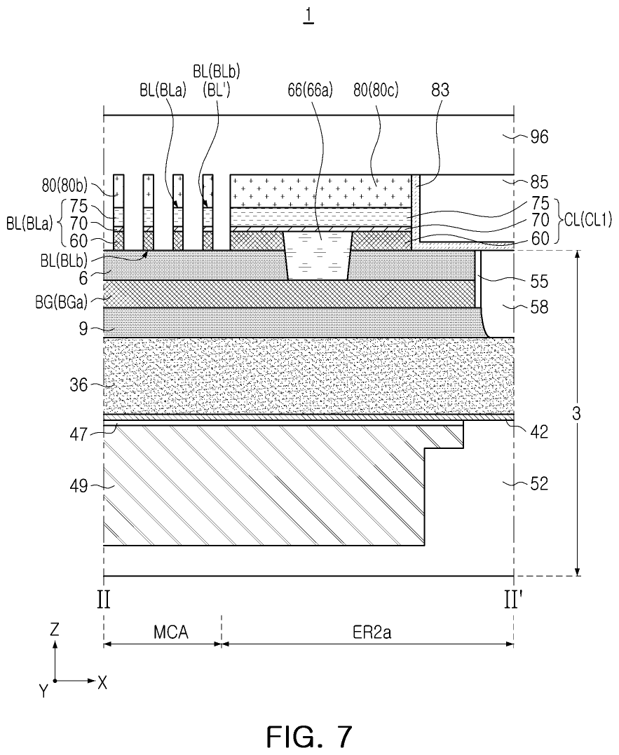

A conductive line adjacent to the first connection line CL1, among the conductive lines BL, may be referred to as a first outer conductive line (BL′ of FIG. 7), and a conductive line adjacent to the second connection line CL2, among the conductive lines BL, may be referred to as a second outer conductive line. For example, the first outer conductive line may be one of the conductive lines BL, which is closest to the first connection line CL1, and the second outer conductive line may be one of the conductive line BL, which is closest to the second connection line CL2. A first spacing between adjacent conductive lines among the conductive lines BL may be different from a second spacing between the first outer conductive line BL′ and the first connection line CL1. For example, the first spacing between adjacent conductive lines among the conductive lines BL may be greater than the second spacing between the first outer conductive line BL′ and the first connection line CL1.

A width of each of the connection lines CL may be greater than a width of each of the conductive lines BL.

The connection lines CL and the conductive lines BL may include the same material. The connection lines CL and the conductive lines BL may include, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, and/or a combination thereof, respectively, but are not limited thereto. Each of the connection lines CL and the conductive lines BL may include a single layer or multiple layers of the conductive materials described above, but are not limited thereto. For example, the connection lines CL and the conductive lines BL may include a lower conductive layer 60, an intermediate conductive layer 70 on the lower conductive layer 60, and an upper conductive layer 75 on the intermediate conductive layer 70, respectively.

The lower conductive layer 60 may include a doped semiconductor material layer. For example, the lower conductive layer 60 may include a silicon layer and/or a silicon-germanium layer. For example, the lower conductive layer 60 may include a polysilicon layer having N-type conductivity. The intermediate conductive layer 70 may include, for example, a metal, a metal compound, and/or a metal-semiconductor compound. For example, the intermediate conductive layer 70 may include Al, Cu, Ti, Ta, Ru, W, Mo, Pt, Ni, Co, TiN, TaN, WN, NbN, TiAl, TiAlN, TiSi, TiSiN, TaSi, CoSi, MoSi, TaSiN, RuTiN, and/or NiSi. For example, the intermediate conductive layer 70 may include a metal semiconductor compound layer and a metal compound layer (e.g., a TiN layer, etc.) on the metal semiconductor compound layer (e.g., a Ti layer, etc.). The upper conductive layer 75 may include, for example, a conductive material having resistivity, lower than resistivity of a material in the lower conductive layer 60. For example, the upper conductive layer 75 may include a conductive material such as W, Mo, Ru, Ni, or the like.

The back gate electrodes BG may overlap the first and second connection lines CL1 and CL2 and the conductive lines BL in a vertical direction (e.g., Z direction).

The back gate contact plugs 66 may be disposed between the back gate electrodes BG and the connection lines CL (in the vertical direction (e.g., Z direction)), to (electrically) connect the back gate electrodes BG and the connection lines CL. Between the back gate electrodes BG and the connection lines CL, the back gate contact plugs 66 may be in contact with the back gate electrodes BG and the connection lines CL.

Between the back gate electrodes BG and the connection lines CL, the back gate contact plugs 66 may extend into (e.g., penetrate) the lower conductive layer 60 of the connection lines CL, and may be (electrically) connected to the connection lines CL. For example, the back gate contact plugs 66 may extend into (e.g., penetrate) the lower conductive layer 60 of the connection lines CL, and may be in contact with the lower conductive layer 60, and upper surfaces of the back gate contact plugs 66 may be in contact with the intermediate conductive layer 70 of the connection lines CL. For example, when viewed based on one first connection line CL1 and one back gate contact plug 66, the back gate contact plug 66 may extend in an upward direction while in contact with the back gate electrode BG, and may be in contact with the first connection line CL1 while penetrating the lower conductive layer 60 of the first connection line CL1. A lower surface of the back gate contact plug 66 may be in contact with the back gate electrode BG, an upper region of a side surface of the back gate contact plug 66 may be in contact with the lower conductive layer 60 of the first connection line CL1, and the upper surface of the back gate contact plug 66 may be in contact with the intermediate conductive layer 70 of the first connection line CL1. The back gate contact plug 66 may have a negatively inclined side surface. For example, a width of an upper region of the back gate contact plug 66 may be greater (larger) than a width of a lower region of the back gate contact plug 66. For example, a cross-sectional view of the back gate contact plug 66 may have a reverse trapezoidal shape. When viewed in a plan view, each of the back gate contact plugs 66 may have a bar shape extending in the first horizontal direction (e.g., X direction).

The back gate contact plugs 66 may include first back gate contact plugs 66a and second back gate contact plugs 66b.

The first back gate contact plugs 66a may be disposed between the first back gate electrodes BGa and the first connection line CL1 (in the vertical direction (e.g., Z direction)), and may (electrically) connect the first back gate electrodes BGa and the first connection line CL1. The second back gate contact plugs 66b may be disposed between the second back gate electrodes BGb and the second connection line CL2 (in the vertical direction (e.g., Z direction)), and may (electrically) connect the second back gate electrodes BGb and the second connection line CL2.

One first connection line CL1 may be (electrically) connected to a plurality of first back gate electrodes BGa through a plurality of first back gate contact plugs 66a. One second connection line CL2 may be (electrically) connected to a plurality of second back gate electrodes BGb through a plurality of second back gate contact plugs 66b.

Each of the back gate contact plugs 66 may include, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, MoSi, CoSi and/or a combination thereof. Each of the back gate contact plugs 66 may include a single layer or multiple layers of the conductive materials described above, but is not limited thereto.

The structure 3 may further include a data storage structure DS and contact structures 33.

The data storage structure DS may be disposed on a level, lower than levels of the cell transistors cTR and the back gate electrodes BG. The contact structures 33 may include cell contact structures 33c and electrically isolated (e.g., electrically separated) dummy contact structures 33d. The cell contact structures 33c may be disposed between the cell transistors cTR and the data storage structure DS, and may (electrically) connect the cell transistors cTR and the data storage structure DS.

Each of the contact structures 33 may include at least one first conductive layer (21 and 24) and at least one second conductive layer (27 and 30) disposed below the at least one first conductive layer (21 and 24). The at least one first conductive layer (21 and 24) may be an extended source/drain region having N-type conductivity. For example, the at least one first conductive layer (21 and 24) may include a semiconductor layer having N-type conductivity. For example, the at least one first conductive layer (21 and 24) may include at least one of an epitaxial silicon layer having N-type conductivity or a polysilicon layer having N-type conductivity. The at least one first conductive layer (21 and 24) may include a 1-1 semiconductor layer 21 and a 1-2 semiconductor layer 24 below the 1-1 semiconductor layer 21. An impurity concentration of the 1-2 semiconductor layer 24 may be greater (higher) than an impurity concentration of the 1-1 semiconductor layer 21. The 1-1 semiconductor layers 21 of the cell contact structures 33c may be (electrically) connected to the first source/drain regions SD1 of the cell transistors cTR.

The data storage structure DS may include first electrodes 45 (electrically) connected to the cell contact structures 33c, a second electrode 49 on (e.g., covering or overlapping) side and lower surfaces of each of the first electrodes 45, and a dielectric layer 47 between the first electrodes 45 and the second electrode 49.

The data storage structure DS may be a memory cell capacitor capable of storing information in a memory such as a DRAM or the like, but embodiments are not limited thereto. For example, the data storage structure DS may be a data storage structure of an MRAM or a data storage structure of an FeRAM.

The structure 3 may further include a gap fill insulating layer 15, gate capping insulating layers 14, lower back gate capping insulating layers 9, upper back gate capping insulating layers 6, and a buffer insulating layer 12.

The gap fill insulating layer 15 may include a portion disposed between cell gate electrodes CG adjacent to each other, and an interlayer insulating portion in the extension regions ER1a, ER1b, ER2a, and ER2b. The gate capping insulating layers 14 may be disposed below lower surfaces of the cell gate electrodes CG. The lower back gate capping insulating layers 9 may be disposed below lower surfaces of the back gate electrodes BG. The upper back gate capping insulating layers 6 may be disposed on upper surfaces of the back gate electrodes BG. The cell gate dielectric layer GOc may be disposed between the cell gate electrodes CG and the active patterns ACTc, and may extend to cover or overlap upper surfaces of the cell gate electrodes CG and an upper surface of the gap fill insulating layer 15. The buffer insulating layer 12 may be disposed on an upper surface of the cell gate dielectric layer GOc, and may have an upper surface that may be coplanar with upper surfaces of the active patterns ACTc. The back gate dielectric layer GOb may be disposed between the back gate electrode BG and the active patterns ACTc, and may extend between the upper back gate capping insulating layer 6 and the active patterns ACTc, and between the lower back gate capping insulating layer 9 and the active patterns ACTc.

The structure 3 may further include an etch stop layer 42, a separation insulating layer 36, and an intermediate interlayer insulating layer 39 disposed in the extension regions ER1a, ER1b, ER2a, and ER2b. The separation insulating layer 36 may be disposed on side surfaces of the contact structures 33, may fill a space between the contact structures 33, and may extend to cover or overlap an upper surface of the intermediate interlayer insulating layer 39 in the extension regions ER1a, ER1b, ER2a, and ER2b. The etch stop layer 42 may be formed of an insulating material including, for example, SiBN, SiCN, SiN, and/or a high-κ dielectric. The etch stop layer 42 may be disposed below the contact structures 33, the separation insulating layer 36, and the intermediate interlayer insulating layer 39. The first electrodes 45 of the data storage structure DS may extend into (e.g., penetrate) the etch stop layer 42, and may be (electrically) connected to the cell contact structures 33c.

The structure 3 may further include a lower capping insulating structure 52 disposed below the etch stop layer 42 and on (e.g., covering or overlapping) side and lower surfaces of the data storage structure DS.

The structure 3 may further include an outer insulating layer 58 and an insulating spacer 55. The outer insulating layer 58 may be disposed on a side surface of the back gate electrode BG, a side surface of the lower back gate capping insulating layer 9, and a side surface of the upper back gate capping insulating layer 6 in the third and fourth extension regions ER2a and ER2b. The insulating spacer 55 may be disposed between the outer insulating layer 58 and the back gate electrode BG, and between the outer insulating layer 58 and the upper back gate capping insulating layer 6.

The first structure ST1 of the semiconductor device 1 may further include capping insulating layers 80. The capping insulating layers 80 may include bit line capping insulating layers 80b disposed on the conductive lines BL and vertically aligned (e.g., vertically overlapped) with the conductive lines BL, and connection capping insulating layers 80c disposed on the connection lines CL and vertically aligned (e.g., vertically overlapped) with the connection lines CL.

The first structure ST1 of the semiconductor device 1 may further include an upper interlayer insulating layer 85, an insulating liner 83, and an upper capping insulating structure 96. The upper interlayer insulating layer 85 may be disposed at outer sides of (adjacent) the connection lines CL and the connection capping insulating layers 80c that may be sequentially stacked in the extension regions ER1a, ER1b, ER2a, and ER2b. The insulating liner 83 may be on (e.g., cover or overlap) side and lower surfaces of the upper interlayer insulating layer 85. The insulating liner 83 may be disposed between the upper interlayer insulating layer 85 and the connection lines CL, and between the upper interlayer insulating layer 85 and the connection capping insulating layers 80c. The upper capping insulating structure 96 may be disposed on the upper interlayer insulating layer 85, the insulating liner 83, the conductive lines BL, the connection lines CL, and the capping insulating layers 80.

The semiconductor device 1 may form (may comprise) a portion of the routing wiring structure (RTa of FIG. 3 or RTb of FIG. 4), and may further include routing conductive patterns BLC and BC (electrically) connected to the bit lines BL and the connection lines CL.

The routing conductive patterns BLC and BC may include bit line contact plugs BLC disposed on the bit lines BL and (electrically) connected to the bit lines BL, and connection contact plugs BC disposed on the connection lines CL and (electrically) connected to the connection lines CL.

The bit line contact plugs BLC may include first bit line contact plugs BLCa (electrically) connected to the first bit lines BLa in the first extension region ER1a, and second bit line contact plugs BLCb (electrically) connected to the second bit lines BLb in the second extension region ER1b. The connection contact plugs BC may include first connection contact plugs BCa adjacent to the first and second extension regions ER1a and ER2a and (electrically) connected to the first connection line CL1, and second connection contact plugs BCb adjacent to the first and second extension regions ER1a and ER2a and (electrically) connected to the second connection line CL2.

In embodiments, the channel regions CH of the cell transistors cTR may be floating bodies, and the back gate electrodes BG facing the channel regions CH may suppress or prevent performance of the cell transistors cTR from being degraded due to a floating body effect.

In embodiments, the connection lines CL adjacent to the conductive lines BL, which may be bit lines, may be used as a path for applying a back gate voltage to the back gate electrodes BG, to stably and efficiently apply a voltage to the back gate electrodes BG.

Hereinafter, various illustrative embodiments of the semiconductor device 1 will be described. The various illustrative embodiments described below and the previously described embodiments may be combined with each other to form one illustrative embodiment. Hereinafter, elements described above may be directly cited without a separate detailed description, or the description may be omitted. In addition, elements described below that may be modified or replaced may be described with reference to the drawings below, but elements that may be modified, replaced, or added may be combined with each other or with the previously described elements to form a semiconductor device according to an embodiment.

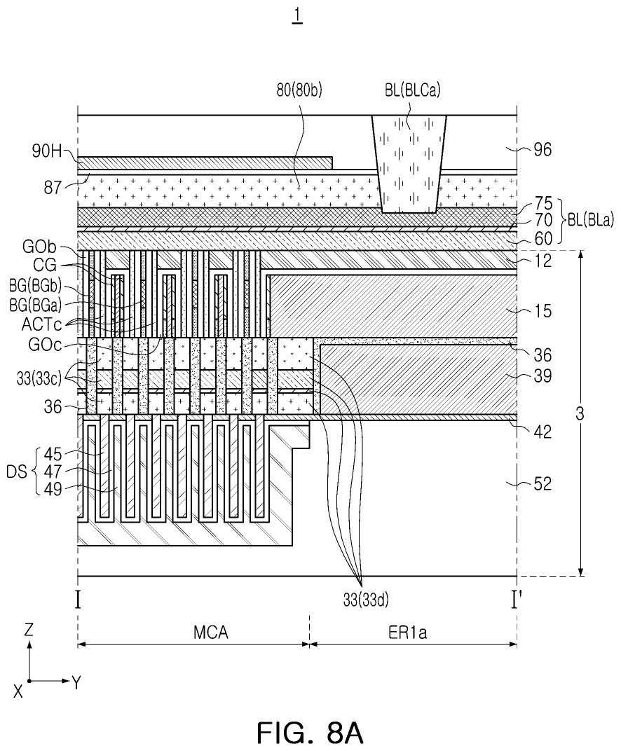

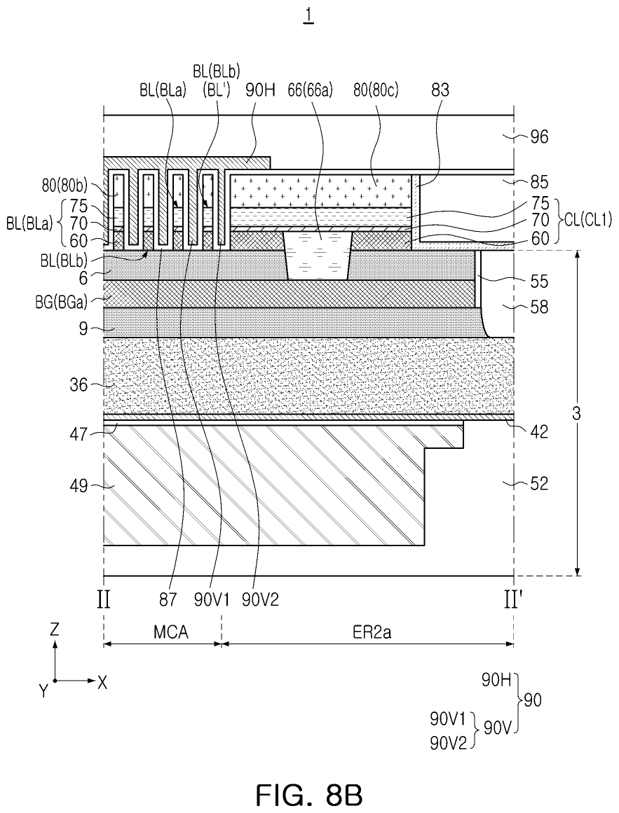

First, with reference to FIGS. 8A and 8B, an illustrative example of a semiconductor device according to an embodiment will be described. FIGS. 8A and 8B are cross-sectional views illustrating an illustrative example of a semiconductor device according to an embodiment, in which FIG. 8A is a cross-sectional view illustrating a region taken along line I-I′ of FIG. 5, and FIG. 8B is a cross-sectional view illustrating a region taken along line II-II′ of FIG. 5.

In an embodiment, referring to FIGS. 8A and 8B, the first structure ST1 of the semiconductor device 1 may further include a conductive shield pattern 90 and a spacer insulating layer 87.

The conductive shield pattern 90 may include vertical portions 90V and a horizontal portion 90H extending from the vertical portions 90V. The horizontal portion 90H may be disposed on the conductive lines BL. The horizontal portion 90H may vertically overlap a portion of each of the connection lines CL. The horizontal portion 90H may be disposed on the capping insulating layers 80. The vertical portions 90V may include first vertical portions 90V1 extending from the horizontal portion 90H in a downward direction and located between the conductive lines BL, and second vertical portions 90V2 extending from the horizontal portion 90H in a downward direction and located between the conductive lines BL and the connection lines CL.

In an embodiment, a width of each of the first vertical portions 90V1 (in the first horizontal direction and/or the second horizontal direction) may be greater than a width of the second vertical portion 90V2 (in the first horizontal direction and/or the second horizontal direction).

The spacer insulating layer 87 may be located between the conductive shield pattern 90 and the conductive lines BL, between the conductive shield pattern 90 and the connection lines CL, and between the conductive shield pattern 90 and the capping insulating layers 80.

The upper capping insulating structure 96 may be on (e.g., may cover or overlap) the conductive shield pattern 90.

The first vertical portions 90V1 of the conductive shield pattern 90 may reduce parasitic capacitance between the conductive lines BL which may be bit lines, and thus may suppress a decrease in signal transmission speed of the bit lines BL.

The second vertical portions 90V2 of the conductive shield pattern 90 may reduce parasitic capacitance between the conductive lines BL and the connection lines CL, and thus may suppress a decrease in signal transmission speed of the connection lines CL.

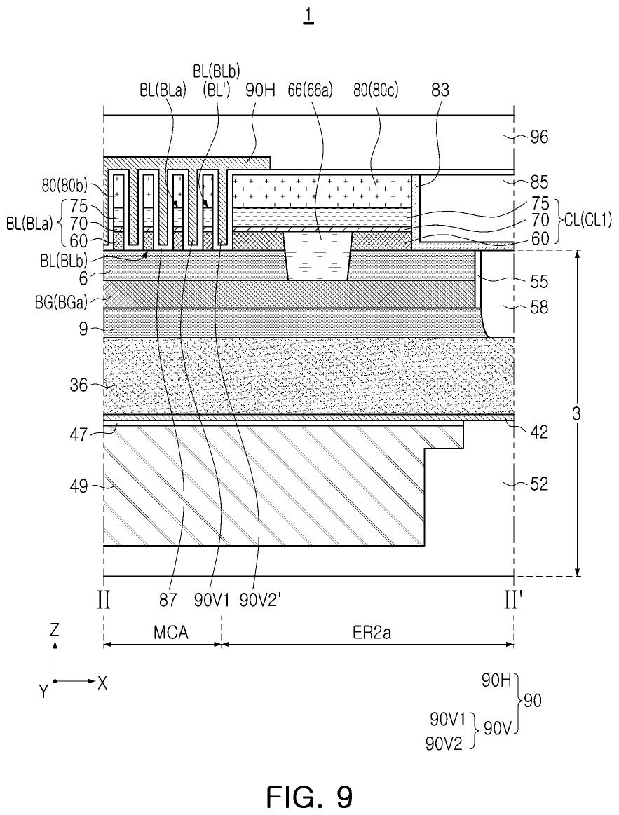

Next, with reference to FIG. 9, an illustrative example of a semiconductor device according to an embodiment will be described. FIG. 9 is a cross-sectional view illustrating an illustrative example of a semiconductor device according to an embodiment, and is a cross-sectional view illustrating a region taken along line II-II′ of FIG. 5.

In an embodiment, referring to FIG. 9, the second vertical portions 90V2 in FIG. 8B may be replaced with second vertical portions 90V2′ having a width (in the first horizontal direction and/or the second horizontal direction), equal to a width of the first vertical portions 90V1 (in the first horizontal direction and/or the second horizontal direction). Therefore, the width of each of the first vertical portions 90V1 and the width of each of the second vertical portions 90V2′ may be (substantially) equal. A spacing between adjacent conductive lines among the conductive lines BL may be (substantially) qual as a spacing between the first outer conductive line BL′ and the first connection line CL1.

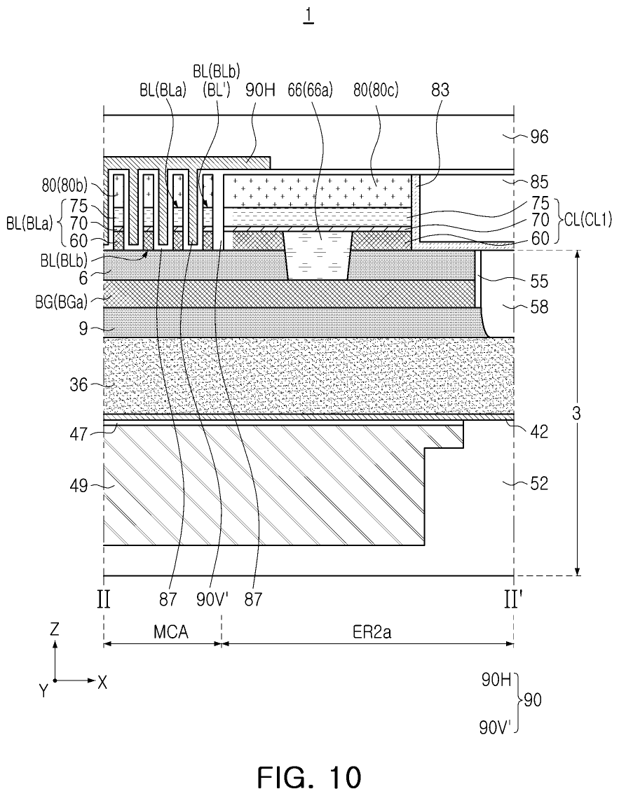

Next, referring to FIG. 10, an illustrative example of a semiconductor device according to an embodiment will be described. FIG. 10 is a cross-sectional view illustrating an illustrative example of a semiconductor device according to an embodiment, and is a cross-sectional view illustrating a region taken along line II-II′ of FIG. 5.

In an embodiment, referring to FIG. 10, the second vertical portions 90V2 in FIG. 8B may be omitted. Therefore, the conductive shield pattern 90 may include first vertical portions 90V′ and the horizontal portion 90H, disposed between the conductive lines BL. A space between the first outer conductive line BL′ and the first connection line CL1 may be filled with the spacer insulating layer 87. For example, the spacer insulating layer 87 may be between the first outer conductive line BL′ and the first connection line CL1. In some embodiments, a spacing between the first outer conductive line BL′ and the first connection line CL1 may be less than half a size of a spacing between adjacent conductive lines BL among the conductive lines BL.

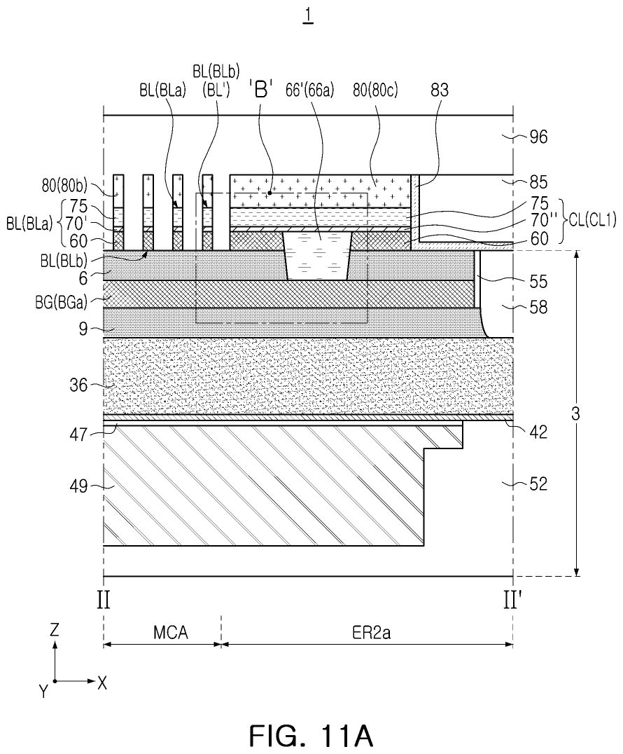

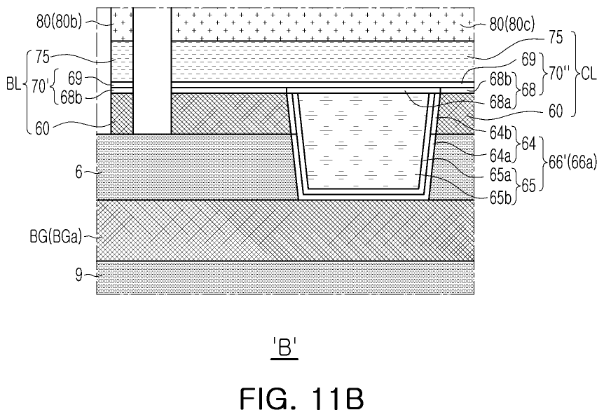

Next, with reference to FIGS. 11A and 11B, an illustrative example of a semiconductor device according to an embodiment will be described. FIG. 11A is a cross-sectional view illustrating an illustrative example of a semiconductor device according to an embodiment, which may be a cross-sectional view illustrating a region taken along line II-II′ of FIG. 5, and FIG. 11B is an enlarged partial view of a region indicated by ‘B’ of FIG. 11A. In this case, the description will focus on one conductive line BL, one connection line CL, and one back gate contact plug 66'.

In an embodiment, with reference to FIGS. 11A and 11B, the intermediate conductive layer 70 of the conductive line BL may be formed as a first intermediate conductive layer 70′ as in FIG. 11B, and the intermediate conductive layer 70 of the connection line CL may be formed as a second intermediate conductive layer 70″ as in FIG. 11B.

The first intermediate conductive layer 70′ of the conductive line BL may include a 1-1 material layer 68b and a second material layer 69 on the 1-1 material layer 68b. The 1-1 material layer 68b of the first intermediate conductive layer 70′ may be in contact with the lower conductive layer 60 of the conductive line BL.

The second intermediate conductive layer 70″ of the connection line CL may include a third material layer 68 and a second material layer 69 on the third material layer 68.

The third material layer 68 of the second intermediate conductive layer 70″ may include a 1-1 material layer 68b contacting the lower conductive layer 60 of the connection line CL, and a 1-2 material layer 68a contacting an upper surface of the back gate contact plug 66′.

The 1-1 material layer 68b of each of the first and second intermediate conductive layers 70′ and 70″ may include, for example, a metal-semiconductor compound layer (e.g., TiSi, CoSi, WSi, NiSi, or MoSi, etc.), and the 1-2 material layer 68a may include, for example, a metal layer (e.g., Ti, Co, W, Ni, or Mo, etc.) including a metal element of the metal-semiconductor compound layer (e.g., TiSi, CoSi, WSi, NiSi, or MoSi, etc.) of the 1-1 material layer 68b. The lower conductive layer 60 may include a doped silicon layer, for example, a polysilicon layer having N-type conductivity.

The back gate contact plug 66′ may include a conductive plug portion 65 and a conductive liner portion 64 on (e.g., covering or overlapping) side and lower surfaces of the conductive plug portion 65.

The conductive liner portion 64 may include a first liner layer 64b contacting the lower conductive layer 60, and a second liner layer 64a not contacting the lower conductive layer 60. The first liner layer 64b may include, for example, a metal-semiconductor compound layer (e.g., TiSi, CoSi, WSi, NiSi, or MoSi, etc.), and the second liner layer 64a may include, for example, a metal layer (e.g., Ti, Co, W, Ni, or Mo, etc.) that may include a metal element of the metal-semiconductor compound layer (e.g., TiSi, CoSi, WSi, NiSi, or MoSi, etc.) of the first liner layer 64b. The first liner layer 64b may be on an upper surface of the second liner layer 64a.

The conductive plug portion 65 may include one or more conductive materials. For example, the conductive plug portion 65 may include a first material layer 65b and a second material layer 65a on (e.g., covering or overlapping) lower and side surfaces of the first material layer 65b. The first material layer 65b may include a material having resistivity, lower than resistivity of a material of the second material layer 65a. The first material layer 65b may include, for example, a metal layer (e.g., W or Mo, etc.), and the second material layer 65a may include, for example, a metal nitride (e.g., TiN, CoN, TaN, WN, etc.). Depending on an embodiment, the conductive plug portion 65 may be formed of a single material of the metal nitride, or may be formed of a single material of the metal.

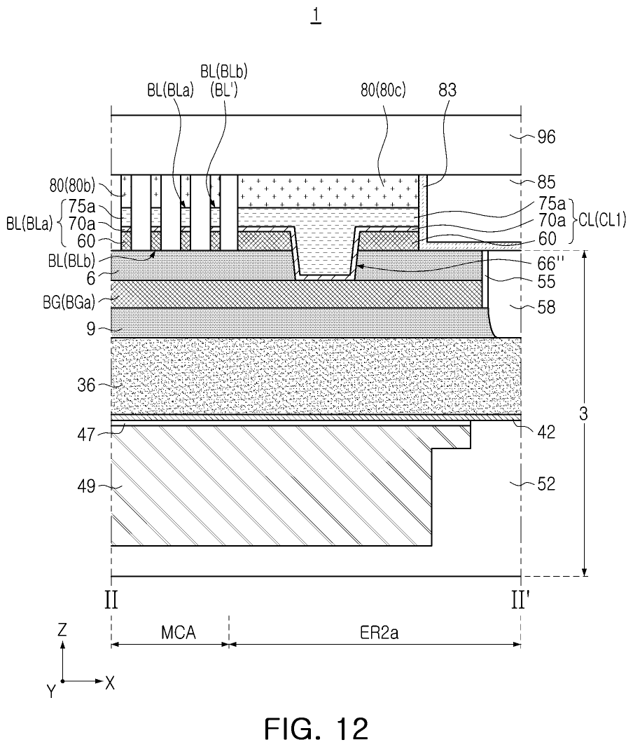

Next, with reference to FIG. 12, an illustrative example of a semiconductor device according to an embodiment will be described. FIG. 12 is a cross-sectional view illustrating an illustrative example of a semiconductor device according to an embodiment, and is a cross-sectional view illustrating a region taken along line II-II′ of FIG. 5. In this case, the description will focus on one conductive line BL, one connection line CL, and one back gate contact plug 66′.

In an embodiment, referring to FIG. 12, each of the conductive line BL and the connection line CL may include a lower conductive layer 60, an intermediate conductive layer 70a, and an upper conductive layer 75a, sequentially stacked. The lower conductive layer 60, the intermediate conductive layer 70a, and the upper conductive layer 75a may be formed of the same material as the lower conductive layer 60, the intermediate conductive layer 70, and the upper conductive layer 75, described above, respectively.

The back gate contact plug 66 described above may be replaced with a back gate contact plug 66″ formed integrally with the intermediate and upper conductive layers 70a and 75a of the connection line CL. Therefore, the intermediate and upper conductive layers 70a and 75a of the connection line CL may extend into (e.g., penetrate) the lower conductive layer 60 of the connection line CL, may extend in a downward direction, and may be (electrically) connected to the back gate electrode BG. Therefore, the intermediate conductive layer 70a of the connection line CL and the back gate contact plug 66″ may extend from a portion interposed between the lower conductive layer 60 and the upper conductive layer 75a to between the upper conductive layer 75a and the back gate electrode BG. Therefore, the intermediate conductive layer 70a of the back gate contact plug 66″ may be in contact with the back gate electrode BG.

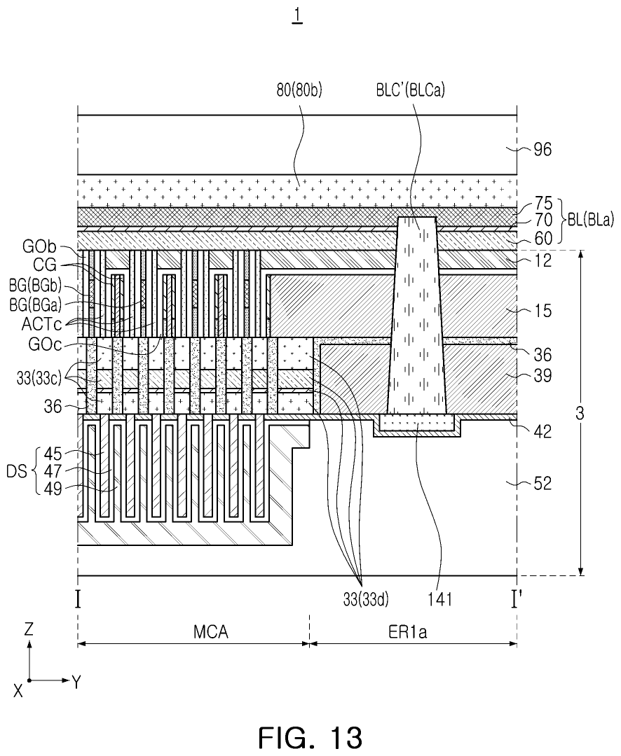

Next, referring to FIG. 13, an illustrative example of a semiconductor device according to an embodiment will be described. FIG. 13 is a cross-sectional view illustrating an illustrative example of a semiconductor device according to an embodiment, and is a cross-sectional view illustrating a region taken along line I-I′ of FIG. 5. In this case, the description will focus on one bit line BL.

In an embodiment, referring to FIG. 13, the bit line contact plug (BLC of FIG. 6A) described above may be replaced with a bit line contact plug BLC′ disposed below (in) the bit line BL. The bit line contact plug BLC′ may be in contact with the bit line BL, and may extend in a downward direction to extend into (e.g., penetrate) the intermediate interlayer insulating layer 39. A routing wiring 141 may be disposed below the intermediate interlayer insulating layer 39. The bit line contact plug BLC′ may (electrically) connect the bit line BL and the routing wiring 141. The etch stop layer 42 may extend to be (e.g., to cover) a lower surface of the routing wiring 141.

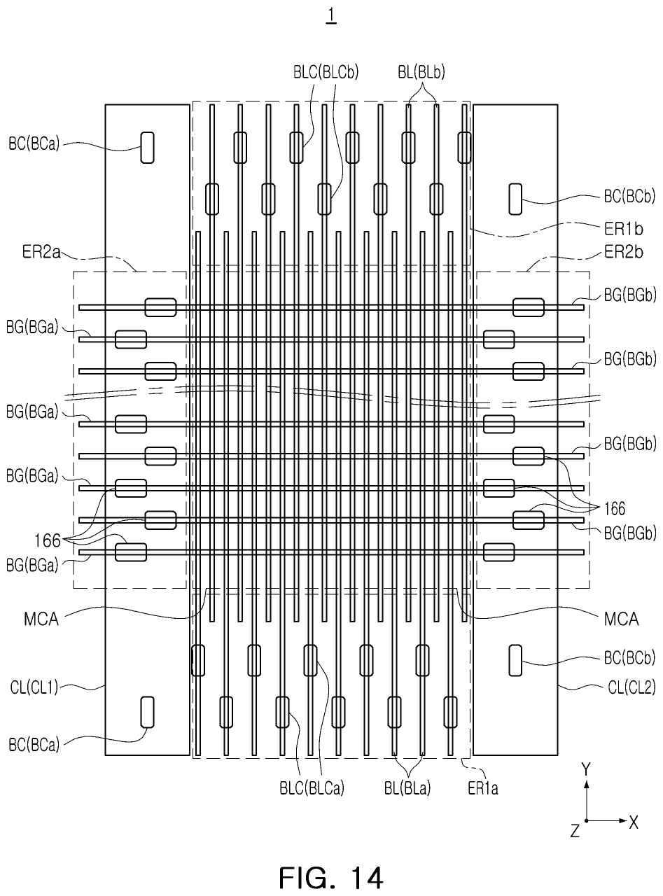

Next, with reference to FIG. 14, an illustrative example of a semiconductor device according to an embodiment will be described. FIG. 14 is a plan view illustrating an illustrative example of a semiconductor device according to an embodiment.

In an embodiment, with reference to FIG. 14, the back gate contact plugs 66 in FIG. 5 may be replaced with back gate contact plugs 166 (electrically) connecting the first and second back gate electrodes BGa and BGb and the first connection line CL1 in the third extension region ER2a, and (electrically) connecting the first and second back gate electrodes BGa and BGb and the second connection line CL1 in the fourth extension region ER2b. For example, one back gate electrode BG may be (electrically) connected to the first connection line CL1 and the second connection line CL2 by the back gate contact plugs 166. Therefore, since one back gate electrode BG may be applied with a voltage through the first and second connection lines CL1 and CL2, a speed at which the voltage is applied to the entire back gate electrode BG may be improved. Therefore, performance of the semiconductor device 1 may be improved.

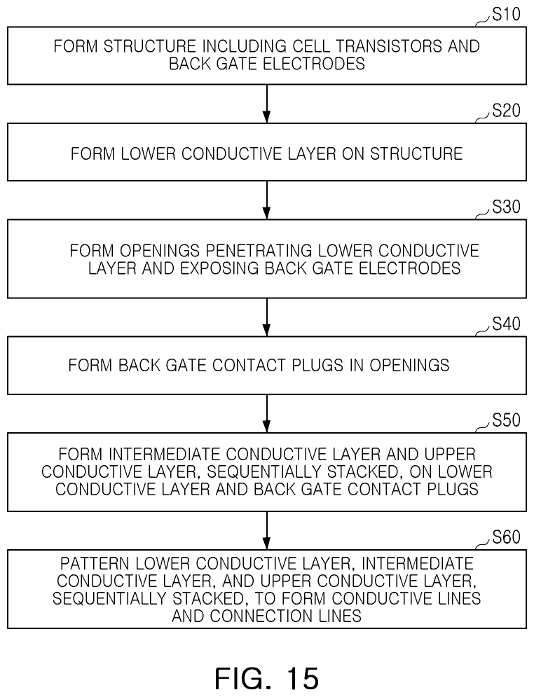

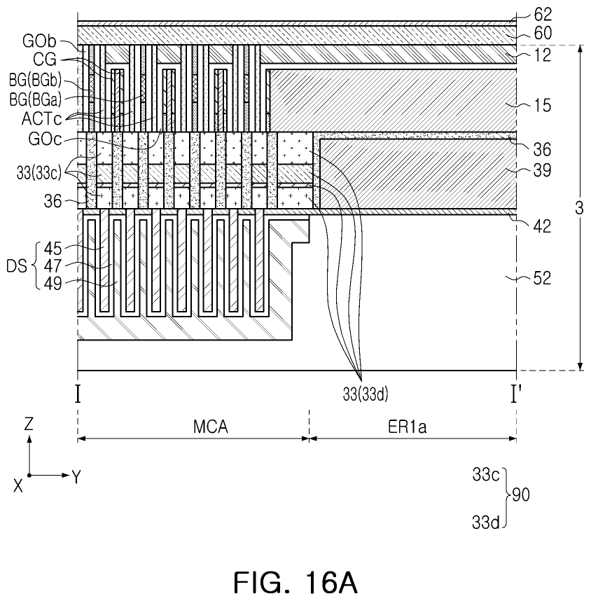

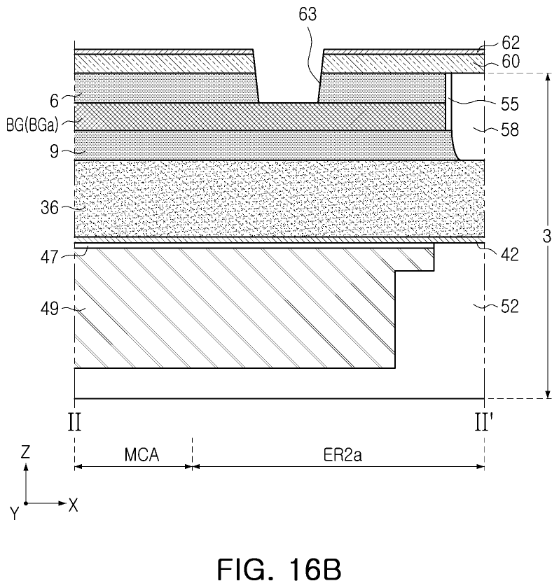

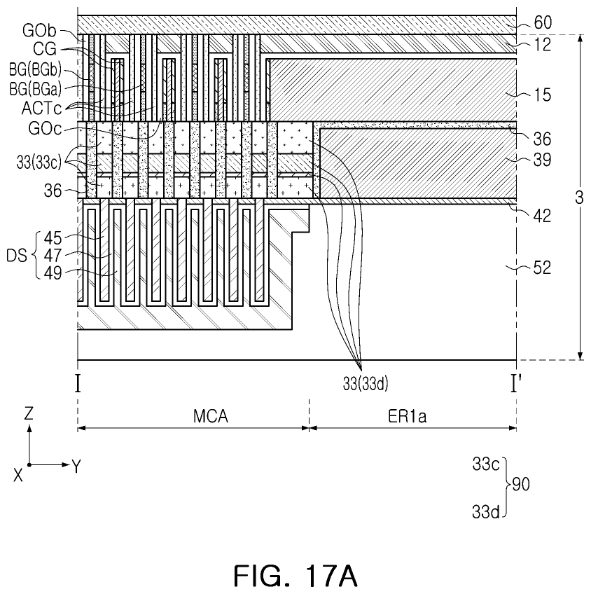

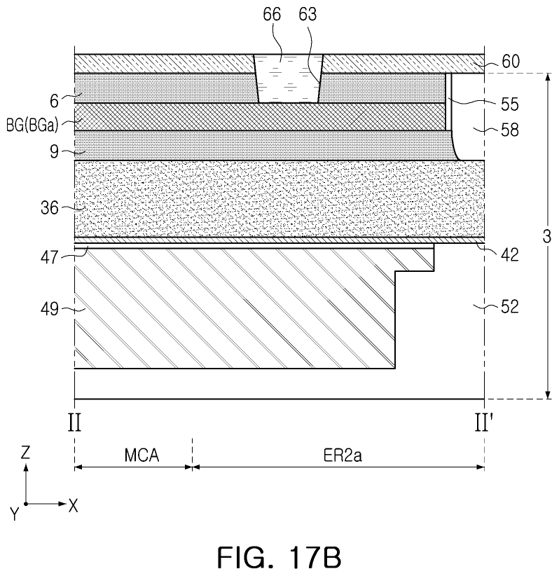

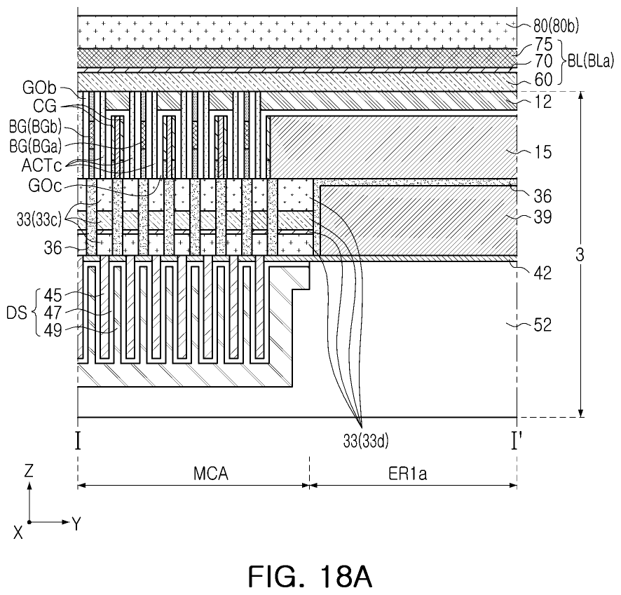

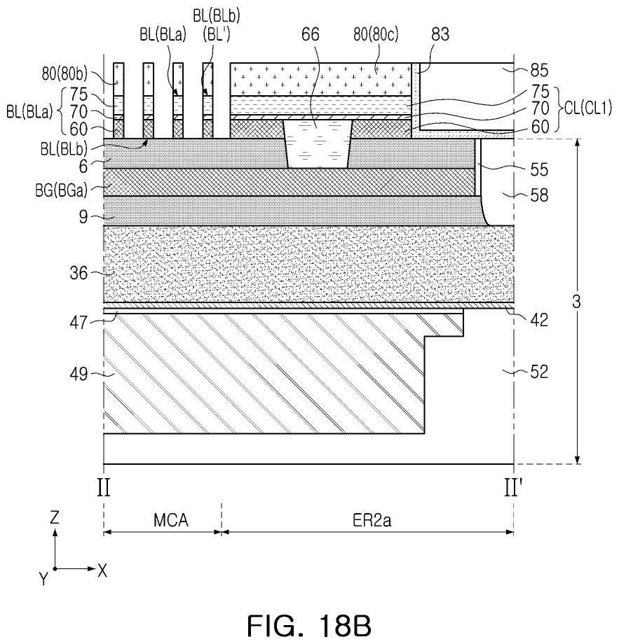

Next, FIGS. 15, 16A, 16B, 17A, 17B, 18A, and 18B are views illustrating an example of a method for forming a semiconductor device according to an embodiment. In FIGS. 15, 16A, 16B, 17A, 17B, 18A, and 18B, FIG. 15 is a process flow diagram illustrating a method for forming a semiconductor device according to an embodiment, FIGS. 16A, 17A, and 18A are cross-sectional views illustrating a region taken along line I-I′ of FIG. 5, and FIGS. 16B, 17B, and 18B are cross-sectional views illustrating a region taken along line II-II′ of FIG. 5.

Referring to FIG. 5, FIG. 15, FIG. 16A, and FIG. 16B, a structure 3 including cell transistors cTR and back gate electrodes BG may be formed (S10). The structure 3 may be the structure 3 described in FIGS. 6A, 6B, and 7. For example, the structure 3 may further include the data storage structure DS and the contact structures 33.

A lower conductive layer 60 may be formed on the structure 3 (S20). A mask layer 62 may be formed on the lower conductive layer 60. Openings 63 penetrating (e.g., recessing) the lower conductive layer 60 and exposing the back gate electrodes BG may be formed (S30). The openings 63 may extend into (e.g., pass through the lower conductive layer 60 and the mask layer 62, sequentially stacked, and may extend in a downward direction, to expose the back gate electrodes BG.

Referring to FIGS. 5, 15, 17A, and 17B, back gate contact plugs 66 may be formed in the openings 63 (S40). The formation of the back gate contact plugs 66 may include forming a conductive material layer filling the openings 63 and covering or overlapping the mask layer 62, and planarizing the conductive material layer until an upper surface of the lower conductive layer 60 is exposed. The mask layer 62 may be removed by the planarization.

Referring to FIGS. 5, 15, 18A, and 18B, an intermediate conductive layer 70 and an upper conductive layer 75, sequentially stacked, may be formed on the lower conductive layer 60 and the back gate contact plugs 66 (S50). An upper interlayer insulating layer 85 may be formed on the upper conductive layer 75. The lower conductive layer 60, the intermediate conductive layer 70, and the upper conductive layer 75, sequentially stacked, may be etched, such that the lower conductive layer 60, the intermediate conductive layer 70, and the upper conductive layer 75, sequentially stacked, remain in the memory cell array region MCA and remain in at least a portion of each of the extension regions ER1a, ER1b, ER2a, and ER2b, and an insulating liner 83 and the upper interlayer insulating layer 85 may be sequentially formed, and the insulating liner 83 and the upper interlayer insulating layer 85 may be planarized.

The lower conductive layer 60, the intermediate conductive layer 70, and the upper conductive layer 75, sequentially stacked, may be patterned to form conductive lines BL and connection lines CL (S60). As the conductive lines BL and the connection lines CL are formed, the capping insulating layers 80 may remain on the conductive lines BL and the connection lines CL.

Referring again to FIGS. 5, 6A, 6B, and 7, an upper capping insulating structure 96 may be formed on the conductive lines BL, the connection lines CL, the capping insulating layers 80, and the upper interlayer insulating layer 85.

In an embodiment, before forming the upper capping insulating structure 96, forming a spacer insulating layer 87 and a conductive shield pattern 90 may be further included, as in FIGS. 8A and 8B.

According to embodiments, a cell transistor including source/drain regions spaced apart from each other in a vertical direction and a channel region between the source/drain regions may be provided. Therefore, a degree of integration of a semiconductor device may increase.

According to embodiments, a back gate electrode facing a portion of a side surface of the channel region, bit lines disposed on levels, higher than a level of the cell transistor, a connection line disposed at substantially the same level as the bit lines and adjacent to the bit lines, and a back gate contact plug electrically connecting the connection line and the back gate electrode, may be provided. A connection line adjacent to the bit lines may be used as a path for applying a back gate voltage to the back gate electrode, to stably and efficiently apply a voltage to the back gate electrode. In addition, since the connection line used as the path for applying the back gate voltage may be formed simultaneously with the bit lines, a degree of integration may increase while simplifying a process thereof, thereby reducing production costs thereof.

In embodiments, the back gate electrode facing the channel region of the cell transistor may suppress or prevent performance of the cell transistor from being degraded due to a floating body effect.

According to embodiments, a degree of integration of the semiconductor device may increase, productivity of the semiconductor device may be improved, and performance of the semiconductor device may be improved.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a cell transistor that includes a channel region;
a back gate electrode that faces a side surface of the channel region and extends in a first horizontal direction;
a bit line on the cell transistor and the back gate electrode, wherein the bit line extends in a second horizontal direction that intersects the first horizontal direction;
a connection line on the back gate electrode, wherein the connection line extends in the second horizontal direction; and
a back gate contact plug between the connection line and the back gate electrode, wherein the back gate contact plug electrically connects the connection line and the back gate electrode,
wherein the bit line overlaps the connection line in the first horizontal direction, and
wherein a first width of the connection line in the first horizontal direction is greater than a second width of the bit line in the first horizontal direction.

2. The semiconductor device of claim 1, wherein the cell transistor further comprises a first source/drain region, a second source/drain region, a cell gate dielectric layer, and a cell gate electrode,
wherein the channel region is on the first source/drain region,
wherein the second source/drain region is on the channel region, and
wherein the bit line is electrically connected to the second source/drain region.

3. The semiconductor device of claim 2, further comprising:
a data storage structure, wherein the cell transistor is on the data storage structure; and
a contact structure between the first source/drain region and the data storage structure, wherein the contact structure electrically connects the first source/drain region and the data storage structure.

4. The semiconductor device of claim 1, wherein each of the bit line and the connection line comprises a lower conductive layer, an intermediate conductive layer on the lower conductive layer, and an upper conductive layer on the intermediate conductive layer.

5. The semiconductor device of claim 4, wherein the back gate contact plug extends into the lower conductive layer of the connection line.

6. The semiconductor device of claim 4, wherein the lower conductive layer of the bit line and the lower conductive layer of the connection line each comprise a polysilicon layer,
wherein the intermediate conductive layer of the bit line and the intermediate conductive layer of the connection line each comprise a metal-semiconductor compound layer and a metal nitride layer on the metal-semiconductor compound layer,
wherein the metal-semiconductor compound layer of the intermediate conductive layer of the bit line is in contact with the lower conductive layer of the bit line,
wherein the metal-semiconductor compound layer of the intermediate conductive layer of the connection line is in contact with the lower conductive layer of the connection line, and
wherein the upper conductive layer of the bit line and the upper conductive layer of thee connection line each comprise a metal layer.

7. A semiconductor device comprising:
a cell transistor;
first back gate electrodes that respectively extend in a first horizontal direction, wherein the first back gate electrodes overlap the cell transistor in a second horizontal direction that intersects the first horizontal direction;
a first connection line and a second connection line on the first back gate electrodes, wherein the first connection line and the second connection line each extend in the second horizontal direction;
bit lines between the first connection line and the second connection line, wherein the bit lines overlap the first connection line and the second connection line in the first horizontal direction and extend in the second horizontal direction; and
first back gate contact plugs between the first back gate electrodes and the first connection line, wherein the first back gate contact plugs electrically connect the first back gate electrodes and the first connection line.

8. The semiconductor device of claim 7, further comprising:
second back gate electrodes that overlap the first back gate electrodes in the second horizontal direction, wherein the second back gate electrodes are alternately arranged with the first back gate electrodes in the second horizontal direction; and
second back gate contact plugs between the second back gate electrodes and the second connection line, wherein the second back gate contact plugs electrically connect the second back gate electrodes and the second connection line.

9. The semiconductor device of claim 8, wherein the first back gate electrodes and the second back gate electrodes overlap the first connection line, the bit lines, and the second connection line in a vertical direction that intersects the first horizontal direction and the second horizontal direction.

10. The semiconductor device of claim 7, wherein each of the first back gate contact plugs has a bar shape extending in the first horizontal direction.

11. The semiconductor device of claim 7, wherein the cell transistor comprises:
a first source/drain region;
a second source/drain region on the first source/drain region;
a channel region between the first source/drain region and the second source/drain region;
a cell gate electrode that has a side surface that faces the channel region; and
a cell gate dielectric layer between the channel region and the cell gate electrode.

12. The semiconductor device of claim 7, further comprising:
a conductive shield pattern that includes vertical portions that extend between the bit lines, and a horizontal portion on the bit lines; and
a spacer insulating layer between the conductive shield pattern and the bit lines.

13. A semiconductor device comprising:
cell transistors;
back gate electrodes between adjacent ones of the cell transistors, wherein the back gate electrodes respectively extend in a first horizontal direction;
conductive lines vertically overlapping the cell transistors and the back gate electrodes, wherein the conductive lines extend in a second horizontal direction that intersects the first horizontal direction;
a first connection line that overlaps the conductive lines in the first horizontal direction and is adjacent a first outermost conductive line among the conductive lines; and
first back gate contact plugs between the first connection line and respective ones of first back gate electrodes of the back gate electrodes,
wherein the first back gate contact plugs electrically connect the first connection line and the respective ones of the first back gate electrodes.

14. The semiconductor device of claim 13, wherein a first width of the first connection line is greater than a second width of each of the conductive lines.

15. The semiconductor device of claim 13, further comprising:
a second connection line that overlaps the conductive lines in the first horizontal direction and is adjacent a second outermost conductive line among the conductive lines; and
second back gate contact plugs between the second connection line and second back gate electrodes of the back gate electrodes,
wherein the second back gate contact plugs electrically connect the second connection line and the second back gate electrodes, and
wherein the conductive lines are between the first connection line and the second connection line in the first horizontal direction.

16. The semiconductor device of claim 13, wherein each of the first connection line and the conductive lines comprises a lower conductive layer, an intermediate conductive layer on the lower conductive layer, and an upper conductive layer on the intermediate conductive layer, and
wherein at least one of the first back gate contact plugs extends into the lower conductive layer of the first connection line and is in contact with the first connection line.

17. The semiconductor device of claim 13, wherein a first spacing between adjacent ones of the conductive lines is different from a second spacing between the first outermost conductive line and the first connection line.

18. The semiconductor device of claim 17, wherein the first spacing is greater than the second spacing.

19. The semiconductor device of claim 13, wherein each of the cell transistors comprises:
a first source/drain region;
a second source/drain region on the first source/drain region;
a channel region between the first source/drain region and the second source/drain region;
a cell gate electrode that faces a side surface of the channel region; and
a cell gate dielectric layer between the channel region and the cell gate electrode,
wherein bit lines among the conductive lines are electrically connected to the second source/drain region of each of the cell transistors.

20. The semiconductor device of claim 19, further comprising:
a data storage structure, wherein the cell transistors are on the data storage structure; and
contact structures between the data storage structure and the first source/drain regions of the cell transistors.
